(19) United States
(12) Patent Application Publication
(10) Pub. No.: US 2008/0218232 A1
(43) Pub. Date: Sep. 11, 2008

(54) TIMING CONTROLLER, DISPLAY DEVICE INCLUDING TIMING CONTROLLER, AND SIGNAL GENERATION METHOD USED BY DISPLAY DEVICE

(76) Inventor: Kyung-ju JEON, Suwon-si (KR)

Correspondence Address: Frank Chau, Esq.;F. CHAU & ASSOCIATES, LLC, 130 Woodbury Road, Woodbury, NY, 11797, US

(21) Appl. No.: 12/039,171

(22) Filed: Feb. 28, 2008

(30) Foreign Application Priority Data
Mar. 7, 2007 (KR) 10-2007-0022409

(51) Int. Cl. H03K 5/01

(52) U.S. Cl. 327/165

(57) ABSTRACT

A display device includes a timing controller and a display unit. The timing controller receives an external clock signal, reads signal generation information, and generates and outputs an internal clock signal based on the read signal generation information. The display unit receives the internal clock signal and displays an image. When the internal clock signal is abnormal, the timing controller rereads the signal generation information and generates and outputs the internal clock signal based on the reread signal generation information.

### CROSS-REFERENCE TO RELATED APPLICATIONS

This application claims priority from Korean Patent Application No. 10-2007-0022409, filed on Mar. 7, 2007, in the Korean Intellectual Property Office, the disclosure of which is incorporated by reference in its entirety herein.

### BACKGROUND OF THE INVENTION

1. Technical Field

The present disclosure relates to a timing controller, a display device including the timing controller, and a signal generation method used by the display device.

2. Discussion of Related Art

A conventional liquid crystal display (LCD) device may include a liquid crystal panel, a gate driver, a data driver, and a timing controller. The liquid crystal panel includes a plurality of gate lines, a plurality of data lines, and a plurality of pixels. The gate driver transmits a plurality of gate signals respectively to the gate lines, and the data driver provides image data to the data lines. The timing controller transmits a plurality of internal clock signals to control the gate driver and the data driver. The timing controller receives external clock signals from an external source, and generates and outputs internal clock signals. The timing controller reads signal generation information, which is required to generate the internal clock signals, from an external memory, stores the read signal generation information in an internal memory, and generates the internal clock signals using the stored signal generation information.

If the signal generation information stored in the internal memory of the timing controller is lost due to, for example, electrostatic discharge (ESD), the conventional LCD device may not operate normally since the internal clock signals may be generated abnormally.

Thus, there is a need for a timing controller which can operate normally despite ESD, a display device including the timing controller, and a signal generation method to drive the display device.

### SUMMARY OF THE INVENTION

According to an exemplary embodiment of the present invention, there is provided a timing controller including a reset unit, a memory controller, and a clock generation unit. The reset unit receives a power supply voltage and provides a first reset signal. The memory controller receives the first reset signal or a second reset signal and reads signal generation information from a first memory. The clock generation unit receives an external clock signal and generates an internal clock signal based on the signal generation information. The second reset signal is provided when the internal clock signal is determined to be abnormal.

According to an exemplary embodiment of the present invention, there is provided a display device including a timing controller and a display unit. The timing controller receives an external clock signal, reads the signal generation information, and generates and outputs an internal clock signal based on the read signal generation information. The display unit receives the internal clock signal and displays an image. When the internal clock signal is abnormal, the timing controller rereads the signal generation information and generates and outputs the internal clock signal based on the reread signal generation information.

According to an exemplary embodiment of the present invention, there is provided a signal generation method used by a display device. The method includes receiving a power supply voltage and reading signal generation information from a memory, receiving an external clock signal and generating and outputting an internal clock signal based on the signal generation information, determining whether the internal clock signal is abnormal, and rereading the signal generation information from the memory and generating and outputting the internal clock signal based on the reread signal generation information when the internal clock signal is determined to be abnormal.

### BRIEF DESCRIPTION OF THE DRAWINGS

The present invention will become more apparent by describing in detail exemplary embodiments thereof with reference to the attached drawings in which:

FIG. 1 is a block diagram of a liquid crystal display (LCD) device according to an embodiment of the present invention;

FIG. 2 is an equivalent circuit diagram of a pixel illustrated in FIG. 1;

FIG. 3 is a block diagram of a timing controller illustrated in FIG. 1;

FIG. 4 is a signal diagram for the timing controller illustrated in FIG. 3;

FIG. 5 is a signal diagram for a determination unit illustrated in FIG. 3;

FIG. 6 is a block diagram of a timing controller according to an exemplary embodiment of the present invention;

FIG. 7 is a block diagram of a timing controller according to an exemplary embodiment of the present invention; and

FIG. 8 is a signal diagram for the timing controller illustrated in FIG. 7.

### DETAILED DESCRIPTION OF EXEMPLARY EMBODIMENTS

The present invention will now be described more fully with reference to the accompanying drawings, in which exemplary embodiments of the invention are shown. Like reference numerals in the drawings may denote like elements.

Hereinafter, a timing controller, a display device including the timing controller, and a signal generation method used by the display device according to exemplary embodiments of the present invention will be described using a liquid crystal display (LCD) device as an example of the display device. However, the present invention is not limited to an LCD device.

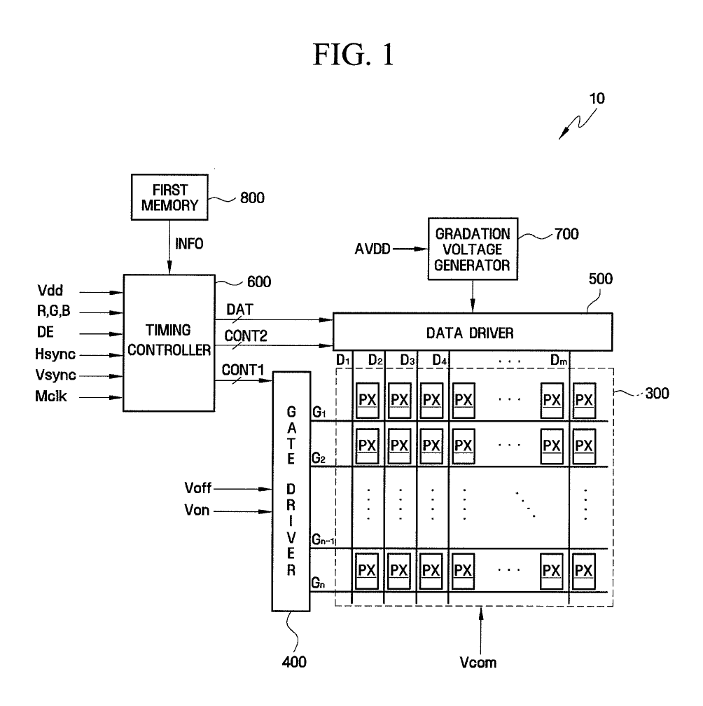

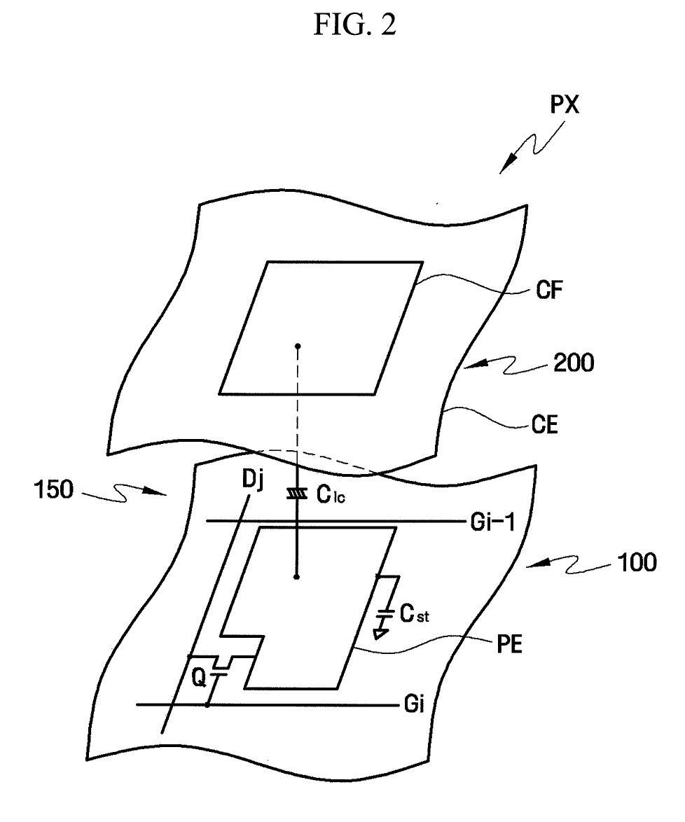

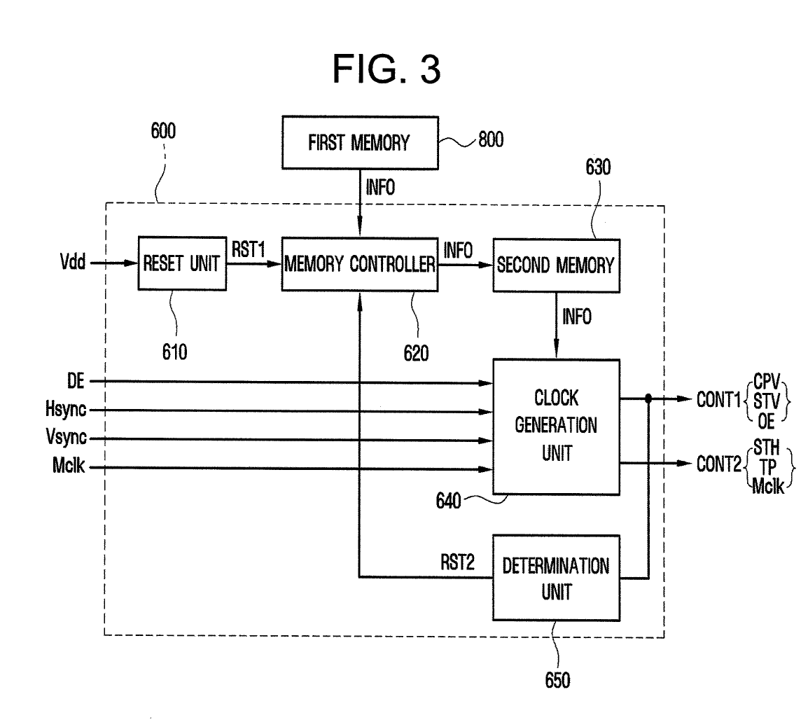

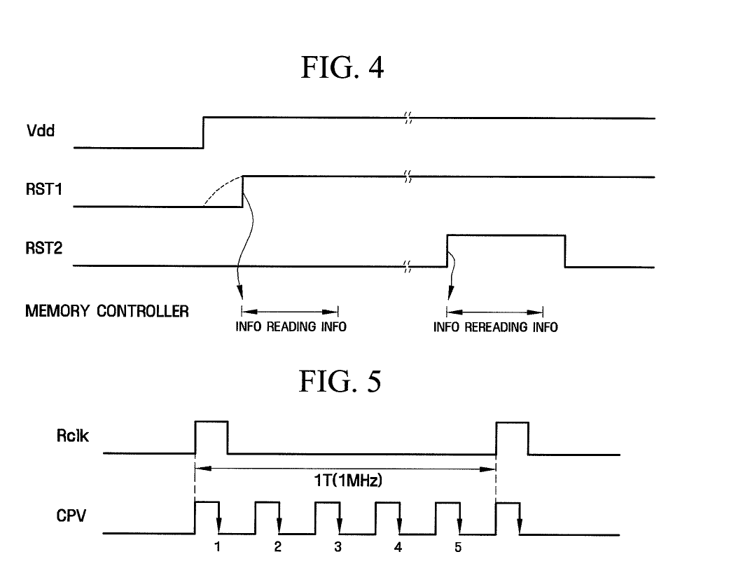

Embodiments of the timing controller, display device, and signal generation method will now be described with reference to FIGS. 1 through 5. FIG. 1 is a block diagram of an LCD device 10. FIG. 2 is an equivalent circuit diagram of a pixel PX illustrated in FIG. 1. FIG. 3 is a block diagram of a timing controller 600 illustrated in FIG. 1. FIG. 4 is a signal diagram for the timing controller 600 illustrated in FIG. 3.

FIG. 5 is a signal diagram for a determination unit 650 illustrated in FIG. 3.

Referring to FIG. 1, the LCD device 10 includes the timing controller 600 and a display unit. The timing controller 600 generates normal internal clock signals despite electrostatic discharge (ESD). The internal clock signals include a gate control signal CONT1 and a data control signal CONT2. The display unit includes a liquid crystal panel 300, a gate driver 400, a data driver 500, and a gradation voltage generator 700.

From the perspective of an equivalent circuit, the liquid crystal panel 300 includes a plurality of display signal lines and a plurality of pixels PX connected to the display signal lines and arranged in a matrix pattern.

The display signal lines include a plurality of gate lines G1 through Gn transmitting a plurality of gate signals and a plurality of data lines D1 through Dm transmitting a plurality of data signals. The gate lines G1 through Gn extend substantially parallel to each other in approximately a row direction, and the data lines D1 through Dm extend substantially parallel to each other in approximately a column direction.

Referring to FIG. 2, the pixel PX of the liquid crystal panel 300 includes a first substrate 100 and a second substrate 200 facing each other and a liquid crystal layer 150 interposed between the first and second substrates 100 and 200. A color filter CF may be formed in a region of a common electrode CE of the second substrate 200 such that the color filter CF faces a pixel electrode PE of the first substrate 100. Each pixel, for example, a pixel connected to an i^{th} (i=1˜n) gate line Gi and a j^{th} (j=1˜m) data line Dj, includes a switching device Q connected to the i^{th} gate line Gi and the j^{th} data line Dj, and a liquid crystal capacitor Clc and a storage capacitor Cst connected to the switching device Q. The storage capacitor Cst may be omitted.

In response to the gate control signal CONT1 transmitted from the timing controller 600, the gate driver 400 applies on and off voltages Von and Voff provided by an external source to the gate lines G1 through Gn.

The data driver 500 receives the data control signal CONT2 and image data DAT from the timing controller 600, selects a gradation voltage corresponding to the image data DAT, and applies the selected gradation voltage to the liquid crystal panel 300.

The gate control signal CONT1 is used to control the operation of the gate driver 400 and includes a vertical start signal STV (see FIG. 3) to start the gate driver 400, a gate clock signal CPV (see FIG. 3) to determine when to output a gate-on voltage, and an output enable signal OE (see FIG. 3) to determine a pulse width of the gate-on voltage.

The data control signal CONT2 is used to control the operation of the data driver 500 and includes a horizontal start signal STH (see FIG. 3) to start the data driver 500 and an output instruction signal TP (see FIG. 3) to instruct the output of a data voltage.

The gradation voltage generator 700 may include a plurality of resistors connected in series between a node, to which a driving voltage AVDD is applied, and a ground. The gradation voltage generator 700 generates a plurality of gradation voltages by distributing the level of the driving voltage AVDD. The internal circuit of the gradation voltage generator 700 is not limited to the configuration of resistors described above and may be variously implemented.

The timing controller 600 receives red, green and blue signals R, G and B and external clock signals to control the display of the red, green and blue signals R, G and B from an external graphic controller (not shown). The external clock signals include a data enable signal DE, a vertical synchronization signal Vsync, a horizontal synchronization signal Hsync, and a main clock signal Mclk. The data enable signal DE remains high while the red, green and blue signals R, G and B are input to indicate that data is present. The vertical synchronization signal Vsync indicates the start of a frame, and the horizontal synchronization signal Hsync distinguishes gate lines. Signals required for the operation of the LCD 10 are synchronized with the main clock signal Mclk.

The timing controller 600 generates the image data DAT based on the received red, green and blue signals R, G and B and provides the generated image data DAT to the data driver 500. In addition, the timing controller 600 generates and outputs the internal clock signals, which include the gate control signal CONT1 and the data control signal CONT2, based on the received external clocks signals, which include the data enable signal DE, the vertical synchronization signal Vsync, the horizontal synchronization signal Hsync, and the main clock signal Mclk. When the timing controller 600 generates the internal clock signals (e.g., CONT1 and CONT2), based on the received external clocks signals (e.g., Vsync, Hsync, Mclk and DE), the timing controller 600 uses signal generation information INFO read from a first memory 800. The signal generation information INFO may include frequency information and output timing information of the internal clock signals. The first memory 800 that stores the signal generation information INFO may be, for example, an electrically erasable programmable read-only memory (EEPROM) or an erasable programmable read-only memory (EPROM). While not illustrated in FIG. 1, the first memory 800 may be included in the timing controller 600.

If the internal clock signals, such as, the gate control signal CONT1 and the data control signal CONT2, are generated abnormally, the timing controller 600 can read the signal generation information INFO from the first memory 800 and regenerate the internal clock signals using the read signal generation information INFO. The timing controller 600 reads the signal generation information INFO from the first memory 800 before generating the internal clock signals and then generates the internal clock signals using the read signal generation information INFO. For example, if the generated internal clock signals are abnormal, the timing controller 600 rereads the signal generation information INFO from the first memory 800 and regenerates the internal clock signals using the reread signal generation information INFO.

The operation of the timing controller 600 will be described in more detail with reference to FIGS. 3 through 5.

Referring to FIGS. 3 and 4, the timing controller 600 includes a reset unit 610, a memory controller 620, a second memory 630, a clock generation unit 640, and the determination unit 650.

When a power supply voltage Vdd is applied to the reset unit 610, the reset unit 610 outputs a first reset signal RST1 at a first level, e.g., a high level, after a predetermined period of time. Alternatively, the reset unit 610 may include a resistor (not shown) and a capacitor (not shown) and output the first reset signal RST1 which gradually transitions to a high level as indicated by a dotted line in FIG. 4 after the power supply voltage Vdd is applied to the reset unit 610. While not illustrated in FIG. 4, the first rest signal RST1 may become high at substantially the same time as when the power supply voltage Vdd is applied to the reset unit 610.

When the first reset signal RST1 transitions to a high level, the memory controller 620 reads the signal generation information INFO from the first memory 800 in synchronization with the first reset signal RST1 and provides the read signal generation information INFO to the second memory 630.

The second memory 630 stores the signal generation information INFO provided by the memory controller 620 and provides the stored signal generation information INFO to the clock generation unit 640. The second memory 630 may be a synchronous dynamic random access memory (SDRAM).

The clock generation unit 640 receives the external clock signals, which include the data enable signal DE, the vertical synchronization signal Vsync, the horizontal synchronization signal Hsync and the main clock signal Mclk, and generates and outputs the internal clock signals, which include the gate control signal CONT1 and the data control signal CONT2, based on the signal generation information INFO. The gate control signal CONT1 includes the vertical start signal STV, the gate clock signal CPV and the output enable signal OE. The data control signal CONT2 includes the horizontal start signal STH, the output instruction signal TP, and the main clock signal Mclk.

The determination unit 650 determines whether the internal clock signals are abnormal. If the signal generation information INFO stored in the second memory 630 is lost, the internal clock signals may be abnormal. For example, the signal generation information INFO stored in the second memory 630 may be lost due to electrostatic discharge (EPD). Since the clock generation unit 640 generates the internal clock signals based on wrong information, the generated internal clock signals may be abnormal.

The determination unit 650 may determine whether the internal clock signals are abnormal by measuring frequencies of the internal clock signals. Referring to FIG. 5, the determination unit 650 includes an oscillator (not shown) generating a reference clock signal Rclk and a counter (not shown). The determination unit 650 counts falling edges of the internal clock signals during a cycle 1T of the reference clock signal Rclk. For example, if a frequency of the gate clock signal CPV generated normally is 5 MHz, the gate clock signal CPV should have five falling edges during a cycle 1T of a 1 MHz reference clock signal Rclk. The counter (not shown) counts falling edges during a period 1T of the reference clock signal Rclk. If the gate clock signal CPV fails to have five falling edges during the period 1T of the reference clock signal Rclk, the determination unit 650 determines that the gate clock signal CPV is abnormal. If the gate control signal CPV has five falling edges during the period 1T of the reference clock signal Rclk, the determination unit 650 determines that the gate clock signal CPV is normal.

The determination unit 650 provides a high-level second reset signal RST2 to the memory controller 620 when it determines that the internal clock signals are abnormal. The determination unit 650 can determine whether one or more of the internal clock signals are normal. For example, the determination unit 650 can determine the normality of internal clock signals in addition to the gate control signal CONT1. Further, the determination unit 650 can determine whether the internal clock signals are normal using methods other than counting the number of falling edges observed during a clock cycle. For example, the determination unit 650 can determine whether the internal clock signals are normal based on whether the frequency of each of the internal clock signals falls within a predetermined frequency range. In addition, a circuit of the determination unit 650 may be variously configured.

In synchronization with the high-level second reset signal RST2, the memory controller 620 rereads the signal generation information INFO from the first memory 800 and provides the reread signal generation information INFO to the second memory 630. The second memory 630 stores the signal generation information INFO provided by the memory controller 620 and provides the stored signal generation information INFO to the clock generation unit 640.

The signal generation information INFO lost from the second memory 630 is reconstructed. Reconstruction may include rereading the signal generation information INFO from the first memory 800 and storing the reconstructed signal generation information INFO in the second memory 630, enabling the clock generation unit 640 to generate the internal clock signals normally.

When reading the signal generation information INFO from the first memory 800, the timing controller 600 may further read image processing information (not shown). The image processing information is a signal used when the timing controller 600 converts the red, green and blue signals R, G and B into the image data DAT. The timing controller 600 receives the image processing information from the second memory 630 and converts the red, green and blue signals R, G and B into the image data DAT. Since the image processing information is also stored in the second memory 630, when the signal generation information INFO is lost from the second memory 630, the image processing information can also be lost. When the image processing information is lost, the red, green and blue signals R, G and B may not be properly converted into the image data DAT, thereby deteriorating display quality.

However, if the internal clock signals, which include the gate control signal CONT1 and the data control signal CONT2, are abnormal, since the memory controller 620 rereads the signal generation information INFO from the first memory 800, the image processing information can also be reread. Since the read signal generation information INFO and image processing information are stored in the second memory 630, the red, green and blue signals R, G and B may be properly converted into the image data DAT at substantially the same time as when the internal clock signals are generated normally. Therefore, the reliability of display quality can be improved.

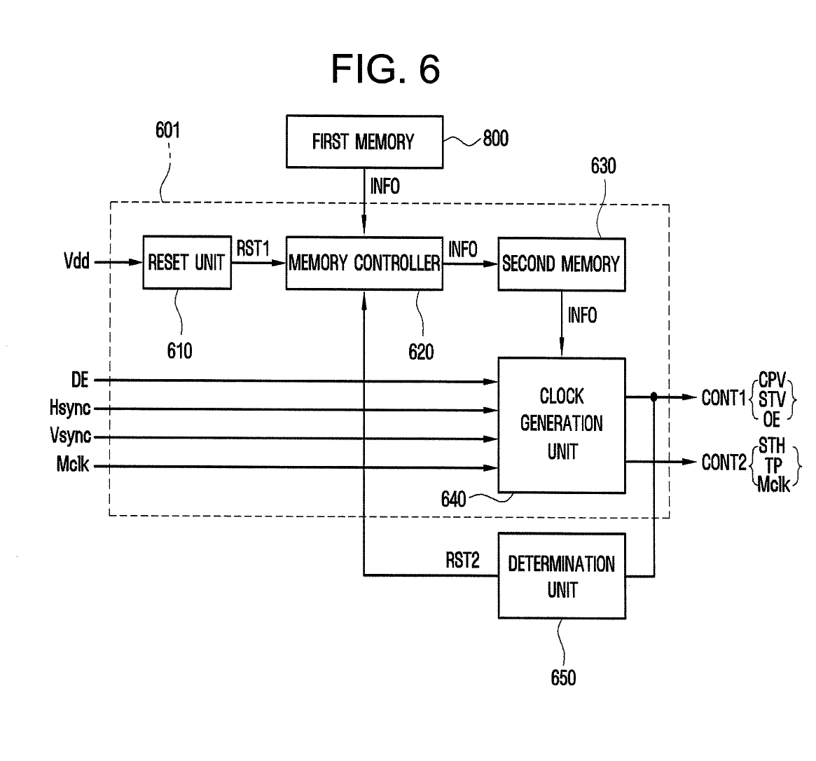

A display device including a timing controller according to an exemplary embodiment of the present invention will be described with reference to FIG. 6. Elements in FIG. 6 having the same functions as those illustrated in FIG. 3 are indicated by like reference numerals, and thus their descriptions will be omitted.

Referring to FIG. 6, a determination unit 650 is disposed outside the timing controller 601. The determination unit 650 determines whether internal clock signals, which include a gate control signal CONT1 and a data control signal CONT2, are abnormal. If the internal clock signals are abnormal, the determination unit 650 transmits a second reset signal RST2 to a memory controller 620 so that the memory controller 620 rereads signal generation information INFO from a first memory 800. The determination unit 650 may include a circuit that measures the frequencies of the internal clock signals. However, the present invention is not limited thereto, as the determination unit 650 may include another type of measurement circuit. For example, the determination unit 650 may include a frequency measurement circuit that determines whether the frequency of an internal clock signal falls within a certain frequency range. The first memory 800 may be included in the timing controller 601.

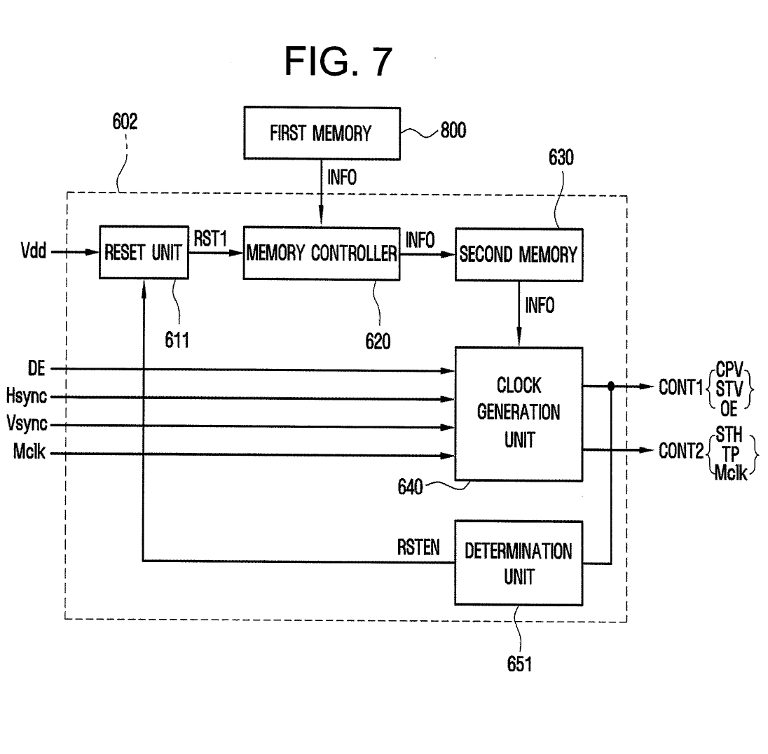

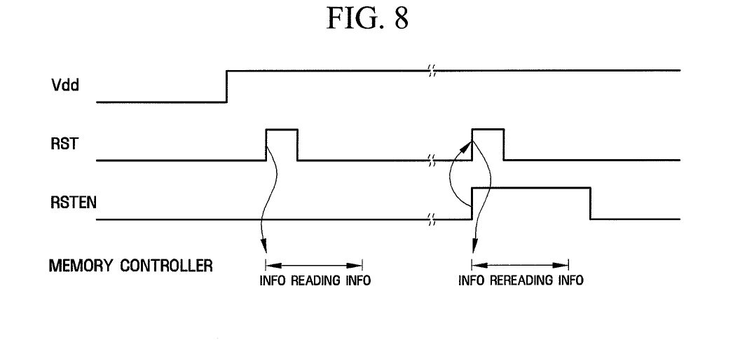

A display device including a timing controller according to an exemplary embodiment of the present invention will now be descried with reference to FIGS. 7 and 8. FIG. 7 is a block diagram of the timing controller 602. FIG. 8 is a signal diagram for the timing controller 602 illustrated in FIG. 7. Elements in FIG. 7 having the same functions as those illustrated in FIG. 3 are indicated by like reference numerals, and thus their description will be omitted. A first memory 800 is disposed outside the timing controller 602. However, the present invention is not limited thereto, as the first memory 800 may be included in the timing controller 602.

A determination unit 651 determines whether internal clock signals, which include a gate control signal CONT1 and a data control signal CONT2, are abnormal and informs a reset unit 611 of the determination result. If the internal clock signals are abnormal, the determination unit 651 transmits a reset enable signal RSTEN to the reset unit 611.

When a power supply voltage Vdd is applied to the reset unit 611, the reset unit 611 outputs a reset signal RST, which transitions from a low level to a high level and then transitions from the high level to the low level.

In synchronization with a rising edge of the reset signal RST, the memory controller 620 reads signal generation information INFO from a first memory 800. Then, the memory controller 620 provides the read signal generation information INFO to a second memory 630.

The second memory 630 stores the read signal generation information INFO and provides the stored signal generation information INFO to a clock generation unit 640. Then, the clock generation unit 640 generates the internal clock signals based on the signal generation information INFO.

If the signal generation information INFO stored in the second memory 630 is lost due to, for example, ESD, the internal clock signals may be output abnormally. The determination unit 651 determines whether the internal clock signals are abnormal and, if the internal clock signals are abnormal, transmits a high-level reset enable signal RSTEN to the reset unit 611. The disposition of the determination unit 651 is not limited to FIG. 7, as the determination unit 651 may also be disposed outside the timing controller 602.

The reset unit 611 is enabled in response to the reset enable signal RSTEN and outputs a reset signal RST which transitions from a low level to a high level and then transitions from the high level to the low level.

The memory controller 620 rereads the signal generation information INFO from a first memory 800 in response to a rising edge of the reset signal RST and provides the reread signal generation information INFO to a second memory 630. While not illustrated in FIG. 8, the memory controller 620 may reread the signal generation information INFO from the first memory 800 when the reset signal RST transitions to a high level after a predetermined period of time from the rising edge of the reset enable signal RSTEN.

The signal generation information INFO lost from the second memory 630 is reconstructed and stored in the second memory 630. Therefore, the clock generation unit 640 generates and outputs the normal internal clock signals based on the signal generation information INFO.

Since the timing controller 602 can generate and output the normal internal clock signals despite, for example, the ESD, a display device including the timing controller can operate normally.

An exemplary embodiment of the present invention enables a display device to operate normally despite ESD, thereby enhancing the reliability of the display device.

While the present invention has been particularly shown and described with reference to exemplary embodiments thereof, it will be understood by those of ordinary skill in the art that various changes in form and detail may be made therein without departing from the spirit and scope of the present invention.

What is claimed is:

1. A display device comprising:
a timing controller to receive an external clock signal, read signal generation information, and generate and output an internal clock signal based on the read signal generation information; and
a display unit to receive the internal clock signal and display an image,
wherein, when the internal clock signal is abnormal, the timing controller rereads the signal generation information and generates and outputs the internal clock signal based on the reread signal generation information.

2. The display device of claim 1, wherein the timing controller determines whether the internal clock signal is abnormal by measuring a frequency of the internal clock signal.

3. The display device of claim 1, further comprising:
a first memory to store the signal generation information; and
a determination unit to determine whether the internal clock signal is abnormal.

4. The display device of claim 3, wherein the timing controller comprises:
a reset unit to receive a power supply voltage and provide a first reset signal;
a memory controller to receive the first reset signal or a second reset signal and read the signal generation information from the first memory; and
a clock generation unit to receive the external clock signal and generate the internal clock signal based on the signal generation information,
wherein the determination unit provides the second reset signal when the internal clock signal is determined to be abnormal.

5. The display device of claim 4, wherein at least the first memory or the determination unit is included in the timing controller.

6. The display device of claim 4, wherein the timing controller further comprises a second memory to receive the signal generation information read by the memory controller, store the received signal generation information, and provide the stored signal generation information to the clock generation unit.

7. The display device of claim 3, wherein the determination unit determines whether the internal clock signal is abnormal by measuring the frequency of the internal clock signal.

8. The display device of claim 3, wherein the timing controller comprises:
a reset unit to receive a power supply voltage or a reset enable signal and provide a reset signal;
a memory controller to receive the reset signal and read the signal generation information from the first memory; and
a clock generation unit to receive the external clock signal and generate the internal clock signal based on the signal generation information,
wherein the determination outputs the reset enable signal when the internal clock signal is determined to be abnormal.

9. The display device of claim 8, wherein at least the first memory or the determination unit is included in the timing controller.

10. The display device of claim 8, wherein the timing controller further comprises a second memory to receive the signal generation information read by the memory controller, store the received signal generation information, and provide the stored signal generation information to the clock generation unit.

11. The display device of claim 1, wherein the timing controller determines whether the internal clock signal is abnormal by counting falling or rising edges of the internal clock signal during a predetermined time.

12. The display device of claim 1, wherein the signal generation information comprises frequency information of the internal clock signal.

13. The display device of claim 1, further comprising:
a first memory external to the timing controller, storing the signal generation information; and;
a second memory internal to the timing controller, receiving the signal generation information read from the first memory,
wherein the timing controller rereads the signal generation information from the first memory when the signal generation information stored in the second memory is lost.

14. A timing controller comprising:
a reset unit to receive a power supply voltage and provide a first reset signal;
a memory controller to receive the first reset signal or a second reset signal and read signal generation information from a first memory; and
a clock generation unit to receive an external clock signal and generate an internal clock signal based on the signal generation information,
wherein the second reset signal is provided when the internal clock signal is determined to be abnormal.

15. The timing controller of claim 14, further comprising a determination unit to determine and provide the second reset signal when the internal clock signal is determined to be abnormal.

16. The timing controller of claim 14, further comprising a second memory to receive the read signal generation information from the memory controller, store the received signal generation information, and provide the stored signal generation information to the clock generation unit.

17. A signal generation method used by a display device, the method comprising:
receiving a power supply voltage and reading signal generation information from a memory;
receiving an external clock signal and generating and outputting an internal clock signal based on the signal generation information;
determining whether the internal clock signal is abnormal; and
rereading the signal generation information from the memory and generating and outputting the internal clock signal based on the reread signal generation information when the internal clock signal is determined to be abnormal.

18. The method of claim 17, wherein the determining of whether the internal clock is abnormal comprises determining whether the internal clock signal is abnormal by measuring a frequency of the internal clock signal.

19. The method of claim 17, wherein the determining of whether the internal clock is abnormal comprises counting falling or rising edges of the internal clock signal during a predetermined time.
